(19) United States
(12) Patent Application Publication
(10) Pub. No.: US 2007/0013066 A1
(43) Pub. Date: Jan. 18, 2007

(54) Semiconductor package and fabrication method thereof

(75) Inventors: Shih-Ming Lin, Taichung (TW); Heng-Cheng Chen, Taichung (TW)

Correspondence Address: BIRCH STEWART KOLASCH & BIRCH, PO BOX 747, FALLS CHURCH, VA, 22040-0747, US

(73) Assignee: Siliconware Precision Industries Co., Ltd.

(21) Appl. No.: 11/486,020

(22) Filed: Jul. 14, 2006

(30) Foreign Application Priority Data
Jul. 15, 2005 (TW) 094124023

(51) Int. Cl. H01L 23/48

(52) U.S. Cl. 257/737

(57) ABSTRACT

A semiconductor package and a fabrication method thereof are provided. The fabrication method includes the steps of preparing a chip having a plurality of conductive bumps formed on an active surface thereof; preparing a tape having a first surface and an opposed second surface, wherein the tape has a plurality of through holes at positions corresponding to the conductive bumps; forming an adhesive layer on the first surface of the tape, and disposing a plurality of leads on the second surface of the tape, so as to make an end of each of the leads covers a corresponding through hole; mounting the active surface of the chip to the adhesive layer on the first surface of the tape and allowing each of the conductive bumps to be received in a corresponding through hole; and performing a heat pressing process to bond the ends of the leads to the conductive bumps in the corresponding through holes. Thereby, an over-temperature problem that occurs during a heat pressing process in the conventional packaging technology can be solved.

### FIELD OF THE INVENTION

The present invention relates to semiconductor packages and fabrication methods thereof, and more particularly, to a chip on film (COF) semiconductor package and a method of fabricating the same.

### BACKGROUND OF THE INVENTION

Tape carrier package (TCP) is a technology that has developed over many years. First, as depicted in FIG. 1A, the TCP technology includes the steps of providing a tape 10 having an opening at the center, wherein a plurality of leads 11 serving as conductive traces are formed thereon and extended into the opening of the tape 10; heat bonding a chip 13 having conductive bumps 12 thereon to the leads 11 by the use of a heat block 15 via tab auto bond (TAB) technology, so as to place that the leads 11 in the opening of the tape 10, in which each of the conductive bumps 12 is connected to each of the corresponding leads 11, such that signals generated from the chip 13 are then transmitted from the chip 13 to conductive bumps 12, through the leads 11, and then to the exterior of the package; and last, as shown in FIG. 1B, employing an encapsulant 18 to encapsulate the opening of the tape 10, leads 11, and a portion of the chip 13, such that the fabrication of a TCP semiconductor package is completed. Applications related to such TCP technology are disclosed in U.S. Pat. Nos. 5,763,940; 5,153,708; 5,250,842; and 5,614,760.

As aforementioned, the TCP technology has been widely used for many years. However, due to the dramatic increase in the functional and performance demands made on electronic products, and the corresponding increase in complexity and integration of semiconductor chips, the TCP technology has encountered difficulties in fabricating ever-miniaturizing but highly-integrated semiconductor package. For example, pitches between bonding pads and conductive bumps in a liquid crystal display (LCD) type of semiconductor chips that TCP technology has been largely used in, have been greatly reduced from 40 μm to 35 μm and even towards 30 μm in recent years. And for that reason, the leads 11 must have sufficient strength to be configured for extending and hanging on the opening of the central tape 10 to be bonded with the semiconductor chip 13. Thus, the width of each of the leads 11 and the pitch therebetween are limited, and can hardly be reduced to fit with highly integrated bonding pads (or conductive bumps). Accordingly, the TCP technology is not suitable in a package having a high density of bonding pads or conductive bumps, and is only applicable to chips with pitch widths down to about 40 μm.

In order to solve this problem, a chip on film (COF) technology has been proposed as illustrated in FIGS. 2A to 2C. Referring to FIG. 2A, a tape/film 20 made of P.I. is disposed with a plurality of leads 21 thereon serving as conductive traces, and then an insulating layer 22 is formed to cover the periphery of the leads 21 to allow the inner end segment of the leads to be exposed from the center of the insulating layer 22. Furthermore, as shown in FIG. 2B, a chip 25 is attached to the tape/film 20, and the conductive bumps 26 formed on the chip 25 are respectively bonded to the corresponding leads 21 using a heat block 29 to form electrical connections between the chip 25 and the leads 21. Last, as shown in FIG. 2C, an insulating material 28 is used to cover the chip 25 and the insulating layer 22, so as to protect the leads 21 and the conductive bumps 26 of the chip 25.

In the aforementioned prior art fabricating method, because the leads 21 are entirely disposed on the tape 20, the tape/film 20 acts as a carrier of the leads and therefore the leads 21 are able to gain more support from the tape/film 20, so as to be firmly secured in position. Accordingly, if the pitch of the leads is decreased to 35 μm or even to 30 μm according to the design of the chip, the width of each lead 21 would be relatively reduced as well, however, with the support of the tape/film 20, the possibility of the occurrence of deformation or breakage of the leads is significantly reduced. As a result, not only solving the forgoing drawbacks of TCP technology, COF technology can also be widely used in packaging products with LCD controller chips. Related applications are disclosed in U.S. Pat. Nos. 6,559,524; 6,864,119; 6,809,406 and 6,710,548.

Inevitably, the COF package has encountered some challenges in fabrication as well. Unlike TCP technology involving direct heating of the conductive bumps and the leads, COF technology involves indirect heating by heating the tape/film 20 (PI material) of high thermal resistance with the heating block 29 first, as shown in FIG. 2b, and then the heat is transferred from the tape/film 20 to the leads 21 and the conductive bumps 26, in order to bond the leads 21 and the conductive bumps 26 together. However, because of this heating process, the cycle time for heating has to be prolonged and the heating block 29 must be heated to a higher temperature such as 300° C. or 450° C., which is difficult to control and may lead to a thermal stress problem, resulting in cracking at the bond points.

Moreover, because the heat is blocked by the tape/film 20, the melting points of the conductive bumps and tin (Sn) of the leads 21 would be difficult to reach, and thus formation of cold bond would occur, lowering the quality of bond points.

Referring to FIG. 2C, apart from the temperature and heating problems described above, the process of applying insulating materials to cover the package is also required to the COF technology, as it does to TCP technology. However, such additional step would increase the cost of production and the complexity of the fabrication processes. Furthermore, if the height of the conductive bumps 26 is not great enough, it may lower fluidity of the mold flow of the insulating material 28, resulting to the occurrence of voids 27 around the periphery of the conductive bumps 26, thereby reducing the quality of the package.

Accordingly, there is a need to develop a semiconductor package and a fabricating method thereof to solve the foregoing drawbacks in the prior art that is applicable in a highly integrated chip package.

### SUMMARY OF THE INVENTION

In order to solve the above-mentioned prior art drawbacks, a primary objective of the present invention is to provide a semiconductor package and a fabricating method thereof that can be applied to a highly integrated chip package.

Another objective of the present invention is to provide a semiconductor package and a fabricating method thereof, which can reduce the temperature of the thermal press process.

Still another objective of the present invention is to provide a semiconductor package and a fabricating method thereof, which can heat leads and conductive bumps of a semiconductor chip directly.

Further another objective of the present invention is to provide a semiconductor package and a fabricating method thereof that can prevent occurrence of thermal stress that leads to damage of bonding points.

Yet another objective of the present invention is to provide a semiconductor package and a fabricating method thereof that can avoid formation of cold bonds.

Another objective of the present invention is to provide a semiconductor package and a fabricating method thereof that does not require the use of an insulating material to encapsulate the package.

Still further another objective of the present invention is to provide a semiconductor package and a fabricating method thereof, which can reduce the cost of production.

In order to achieve the foregoing and other objectives, the present invention proposes a fabricating method of a semiconductor package, comprising the steps of: preparing a chip having an active surface, wherein a plurality of conductive bumps are formed on the active surface; preparing a tape having a first surface and an opposed second surface, wherein the tape has a plurality of through holes penetrating through the first and second surfaces at positions corresponding to the conductive bumps; forming an adhesive layer on the first surface of the tape and disposing a plurality of leads on the second surface of the tape, wherein an end of each of the leads covers one of the plurality of corresponding through holes; mounting the active surface of the chip to the adhesive layer on the first surface of the tape and allowing each of the conductive bumps to be placed in each corresponding through hole; and performing a heat pressing process to bond the ends of the leads to the conductive bumps in the corresponding through holes.

The semiconductor package proposed by the present invention, comprises: a tape having a first surface and an opposing second surface, wherein the tape is formed with a plurality of through holes penetrating the first surface and the second surface; an adhesive layer formed on the first surface of the tape; a plurality of leads disposed on the second surface of the tape, wherein an end of each of the leads covers one of the corresponding through holes; and a chip having a plurality of conductive bumps mounted on the active surface thereof, wherein the active surface is mounted to the adhesive layer of the first surface of the tape, in which the conductive bumps are positioned corresponding to the through holes on the tape, such that each conductive bump is placed in a corresponding through hole, so as to allow an end of each of the leads to be boned with a corresponding conductive bump in the through holes.

The semiconductor package of the present invention may further comprise an insulating layer covering the plurality of leads. The insulating layer can either completely cover each of the leads, or allow an end of each of the leads to be exposed from the insulating layer. Furthermore, the through holes are exposed from the adhesive layer, and the thickness of the tape is equal to or smaller than the height of the conductive bumps, such that each of the conductive bumps is slightly protruded from the through holes and connected with an end of each of the corresponding leads.

The foregoing tape may be made of polyimide (PI) material, and the adhesive material may be made of PI or silicone. Additionally, the adhesive layer may cover the entire area of the first surface of the tape, or just the chip attachment area of the first surface of the tape.

Accordingly, in the semiconductor package proposed by the present invention, the leads thereof are disposed on the second surface of the tape and therefore are able to gain support from the tape instead of hanging on the air. As a result, the pitch of the leads can be significantly reduced according to the size of the chip, without the need to address breakage concerns. Moreover, as the chip is directly attached to the adhesive layer of the first surface of the tape, there is no need to perform another process of forming encapsulant, thereby reducing material and fabrication costs, as well as eliminating the problem of voids due to uneven filling of the mold. In addition, another advantage of the present invention is that, during the heat pressing process, the leads are directly heated by the heat block, thereby significantly reducing the time required to reach the melting point, as well as solving difficulties in process control and the over-temperature problem existing in the prior art.

### BRIEF DESCRIPTION OF THE DRAWINGS

The present invention can be more fully understood by reading the following detailed description of the preferred embodiments, with reference made to the accompanying drawings, wherein:

FIGS. 1A-1B (PRIOR ART) are schematic cross-sectional views showing procedural steps of fabricating method for a conventional tape carrier package (TCP);

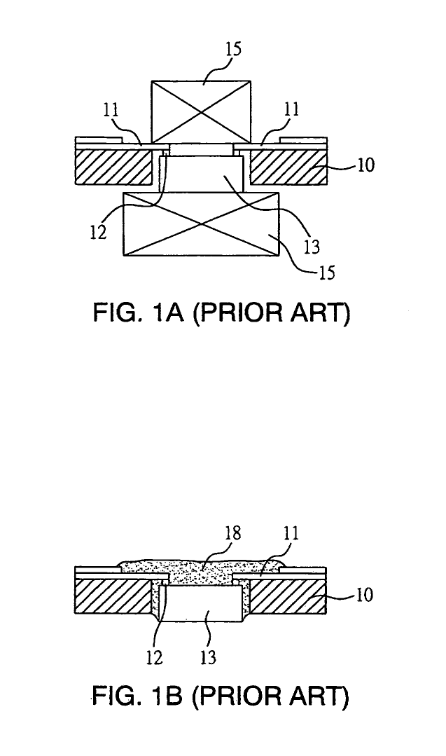

FIGS. 2A-2C are schematic cross-sectional views showing procedural steps of a fabricating method for a conventional chip on film (COF) package;

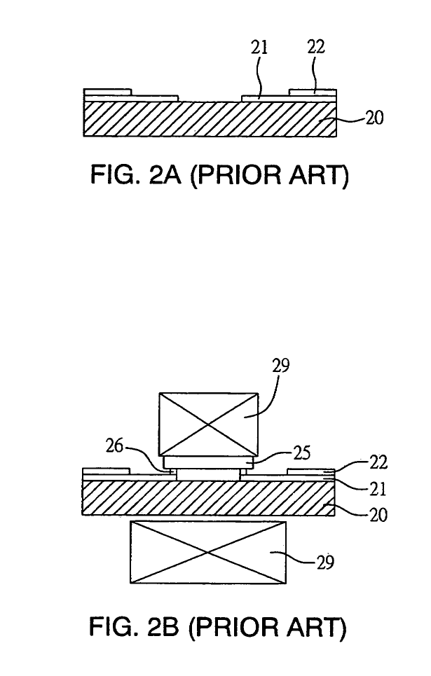

FIGS. 3A-3E are schematic cross-sectional views showing procedural steps of a fabricating method for a semiconductor package in accordance with the present invention;

FIG. 4 is a schematic cross-sectional view of a semiconductor package in accordance with a preferred embodiment of the present invention;

FIG. 5 is a schematic cross-sectional view of a semiconductor package in accordance with another preferred embodiment of the present invention; and

FIG. 6 is a schematic cross-sectional view of a semiconductor package in accordance with yet another preferred embodiment of the present invention.

### DETAILED DESCRIPTION OF THE PREFERRED EMBODIMENTS

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawing FIGs. Similarly, although the views in the drawings for ease of description generally show similar orientations, this depiction in the FIGs. is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

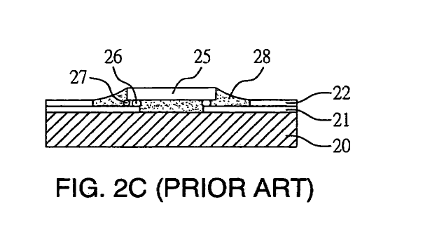

As shown in FIGS. 3A to 3E, the present invention proposes a fabricating method of a semiconductor package. First, as shown in FIG. 3A, a flip chip 30 having a plurality of conductive bumps 32 formed on an active surface 31 of the chip 30 is prepared, wherein the conductive bumps 32 may be made of gold (Au). Then, as shown in FIG. 3B, a tape 35 having a first surface 351 and an opposing second surface 352 is prepared, wherein the tape 35 is made of made of PI, and the thickness of the tape 35 is equal to or smaller than the height of the conductive bumps 32 (the preferred height of the conductive bumps 32 ranging from 15 μm to 30 μm). Furthermore, the tape 35 is formed with a plurality of through holes 36 penetrating through the first surface 351 and the second surface 352 at positions corresponding to the conductive bumps 32, wherein the through holes 36 are located about the center of the tape 35, that is, within the chip attachment area on the tape 35. In addition, the first surface 351 of the tape 35 is further formed with an adhesive layer 40 that may be made of high molecular material such as PI or silicone, wherein the adhesive layer 40 may contain a plurality of openings to expose the through holes 36.

A plurality of leads 43 are formed on the second surface 352 of the tape 35, allowing an inner end 430 of each of the leads 43 to cover the corresponding through hole 36, such that the through holes 36 facing toward the second surface 352 are covered by the corresponding ends 430 of the leads 43. In addition, the second surface 352 of the tape 35 may further comprise an insulating layer 45 formed on most of the leads 43, so as to cover and protect the leads 43. Moreover, an opening is formed at about the center of the insulating layer 45, so as to expose the inner ends 430 of the leads 43.

Furthermore, as shown in FIG. 3C, the active surface 31 of the chip 30 is mounted to the adhesive layer 40 of the first surface 351 of the tape 35. And then the chip 30 is heated, so that it can be adhered to the adhesive layer 40 and thereby secured in position on the first surface 351 of the tape 35, while allowing each of the conductive bumps 32 to be placed in each of the corresponding through holes 36, wherein the conductive bumps 32 slightly protruding from the through holes 36 are connected to the corresponding lead ends 430. Last, as shown in FIG. 3D, a heat pressing process is performed using a conventional heat block 50 to heat the leads 43 to allow the inward ends 430 of the leads 43 to be fusion bonded to the corresponding conductive bumps 32 in the through holes 36, so as to form electrical connections. The finished semiconductor package is shown in FIG. 3E, in which signals from the chip 30 (such as an LCD controller chip) can be transmitted from the conductive bumps 32 to the lead ends 430 via the conductive bumps 32, and then transmitted via the leads 43 to an external electronic device (such as a printed circuit board).

Therefore, the semiconductor package proposed by the present invention comprises the leads 43 disposed on the second surface 352 of the tape 35, which are capable of gaining support from the tape 35 instead of hanging on the air. This thereby allows the pitch of the leads 43 to be significantly reduced as required to match the size of the chip 30, without the need to address concerns about possible breakage of the leads 43. Furthermore, as the chip 30 is directly attached to the adhesive layer 40 of the first surface 351 of the tape 35, there is no need to perform another process of forming an encapsulant, thereby reducing material and fabrication costs, as well as preventing occurrence of voids due to uneven filling of the mold. In addition, another advantage of the present invention is that, the leads 43 are directly heated by the heat block 50 during the heat pressing process, so that the time required to reach the melting point can be reduced significantly, thereby solving difficulties in controlling the fabricating processes and problems of over-temperature existing in the prior art.

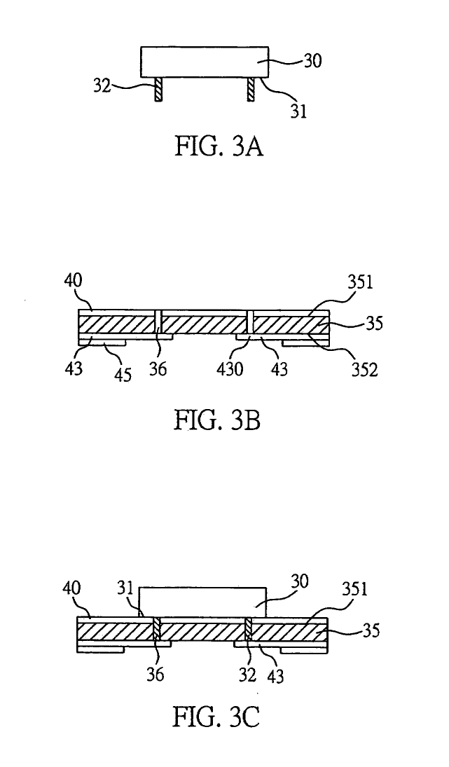

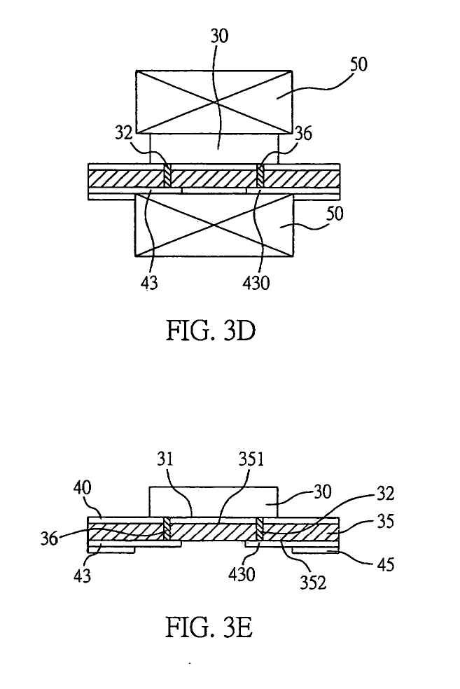

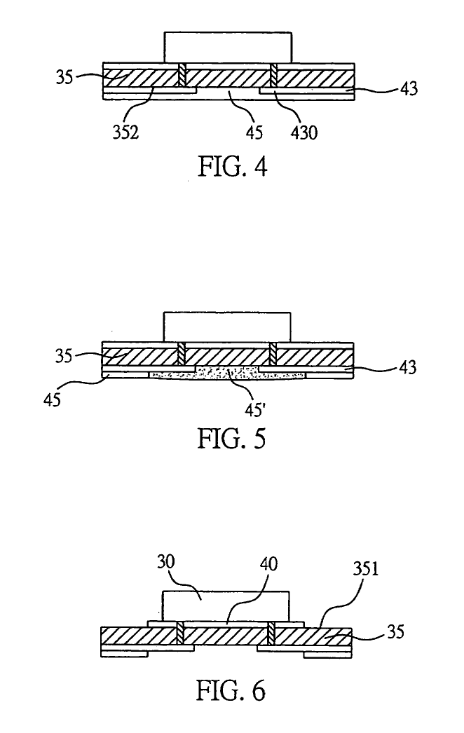

The above-mentioned insulating layer 45 may be formed in a way that the lead ends 430 are exposed therefrom, or, alternatively, as shown in FIG. 4, completely covering the second surface 352 of the tape 35 so as to protect the leads 43. Yet another alternative, as shown in FIG. 5, involves a second insulating layer 45′ being formed to cover the leads exposed from the insulating layer 45. Apart from using the adhesive layer 40 to completely cover the entire first surface 351 of the tape 35, the adhesive layer 40 may also be employed for covering just a portion of the tape 35, such as the chip attachment area on the first surface 351 of the tape 35, as shown in FIG. 6.

Referring to FIG. 3E, the semiconductor package fabricated according to a preferred embodiment of the present invention comprises: a tape 35 having first surface 351 and an opposing second surface 352, wherein a plurality of through holes 36 are formed on the tape 35 and penetrating the first surface 351 and the second surface 352 thereof; an adhesive layer 40 formed on the first surface 351 of the tape 35; a plurality of leads 43 disposed on the second surface 352 of the tape 35, wherein an end 430 of each of the leads 43 covers each of the corresponding through holes 36; and a chip 30 having a plurality of conductive bumps 32 mounted on the active surface 31 thereof, wherein the active surface 31 is mounted on the adhesive layer 40 of the first surface 351 of the tape 35, and the conductive bumps 32 are positioned corresponding to the through holes 36 on the tape, allowing each of the conductive bumps to be placed in a corresponding through hole 36, such that the ends 430 of each leads 43 can be bonded with the corresponding conductive bumps 32 in the through holes 36 by a fusion bonding process.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A fabricating method of a semiconductor package, comprising the steps of:
preparing a chip having a plurality of conductive bumps on an active surface thereof;
preparing a tape having a first surface and an opposed second surface, wherein the tape has a plurality of through holes penetrating through the first and second surface at positions corresponding to the conductive bumps;
forming an adhesive layer on the first surface of the tape and disposing a plurality of leads on the second surface of the tape, wherein an end of each of the leads covers one of the plurality of corresponding through holes;
mounting the active surface of the chip to the adhesive layer on the first surface of the tape, such that each of the conductive bumps is placed in one of the plurality of corresponding through holes; and
performing a heat pressing process to bond the ends of the leads to the conductive bumps in the corresponding through holes.

2. The fabricating method of the semiconductor package of claim 1, wherein the semiconductor package further comprises an insulating layer covering most of the leads.

3. The fabricating method of the semiconductor package of claim 2, wherein the insulating layer completely covers the entirety of the leads.

4. The fabricating method of the semiconductor package of claim 2, wherein the ends of the leads are exposed from the insulating layer.

5. The fabricating method of the semiconductor package of claim 4, wherein the semiconductor package further comprises a second insulating layer for covering the leads exposed from the insulating layer.

6. The fabricating method of the semiconductor package of claim 1, wherein the thickness of the tape is equal to or smaller than the height of the conductive bumps.

7. The fabricating method of the semiconductor package of claim 1, wherein the tape is made of polyimide.

8. The fabricating method of the semiconductor package of claim 1, wherein the adhesive layer is made of a material selected from at least one of polyimide and silicone.

9. The fabricating method of the semiconductor package of claim 1, wherein the adhesive layer completely covers the surface of the first surface of the tape.

10. The fabricating method of the semiconductor package of claim 1, wherein the adhesive layer only covers the chip attachment area on the first surface of the tape.

11. A semiconductor package, comprising:
a tape having a first surface and an opposing second surface, wherein a tape is formed with plurality of through holes penetrating the first surface and the second surface thereof;
an adhesive layer formed on the first surface of the tape;
a plurality of leads disposed on the second surface of the tape, wherein each of the ends of the leads covers one of the through holes; and
a chip having a plurality of conductive bumps mounted on the active surface thereof, wherein the conductive bumps are at positions corresponding to the plurality of through holes, such that the conductive bumps are placed in the corresponding through holes, so as to allow an ends of each of the leads to be bonded to each of the conductive bumps positioned in each of the corresponding through holes by a fusion bonding process.

12. The semiconductor package of claim 11, wherein the semiconductor package further comprises an insulating layer covering the plurality of leads.

13. The semiconductor package of claim 12, wherein the insulating layer completely covers the entirety of the leads.

14. The semiconductor package of claim 12, wherein the ends of the leads are exposed from the insulating layer.

15. The semiconductor package of claim 14, wherein the semiconductor package further comprises a second insulating layer for covering the leads exposed from the insulating layer.

16. The semiconductor package of claim 11, wherein the thickness of the tape is equal to or smaller than the height of the conductive bumps.

17. The semiconductor package of claim 11, wherein the tape is made of polyimide.

18. The semiconductor package of claim 11, wherein the adhesive layer is made of a material selected from at least one of polyimide and silicone.

19. The semiconductor package of claim 11, wherein the adhesive layer completely covers the surface of the first surface of the tape.

20. The semiconductor package of claim 11, wherein the adhesive layer only covers the chip attachment area on the first surface of the tape.
